(19) United States
(12) Patent Application Publication
(10) Pub. No.: US 2021/0125862 A1
(43) Pub. Date: Apr. 29, 2021

(54) SUPER VIA INTEGRATION IN INTEGRATED CIRCUITS

(71) Applicant: QUALCOMM Incorporated, San Diego, CA (US)

(72) Inventors: John Jianhong ZHU, San Diego, CA (US); Junjing BAO, San Diego, CA (US); Jun CHEN, San Diego, CA (US); Giridhar NALLAPATI, San Diego, CA (US)

(21) Appl. No.: 16/664,677

(22) Filed: Oct. 25, 2019

(51) Int. Cl. H01L 21/768

(52) U.S. Cl. CPC H01L 21/76879

(57) ABSTRACT

Aspects of the disclosure are directed to super via integration. In accordance with one aspect, an apparatus with super via integration in an integrated circuit including a first metal layer; a second metal layer, wherein the second metal layer is adjacent to the first metal layer; a third metal layer, wherein the third metal layer is adjacent to the second metal layer and is non-adjacent to the first metal layer; and a super via interconnecting the first metal layer and the third metal layer through a dielectric material, wherein the super via is filled with a selective metal.

### TECHNICAL FIELD

This disclosure relates generally to the field of integrated circuits, and, in particular, to super via integration in integrated circuits.

### BACKGROUND

Integrated circuits (e.g., chips) may include a plurality of semiconductor devices, such as transistors, to perform a desired set of functions. For example, transistors may be metal oxide semiconductor (MOS) transistors. Integrated circuits (ICs) may be manufactured with billions of transistors on a single monolithic device. To further improve IC capability, increased scalability is desired. One form of increased scalability is the integration of super vias in the integrated circuits (IC).

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides super via integration. Accordingly, an apparatus with super via integration in an integrated circuit, the apparatus including: a first metal layer; a second metal layer, wherein the second metal layer is adjacent to the first metal layer; a third metal layer, wherein the third metal layer is adjacent to the second metal layer and is non-adjacent to the first metal layer; and a super via interconnecting the first metal layer and the third metal layer through a dielectric material, wherein the super via is filled with a selective metal.

In one example, the super via is filled into a trench in the dielectric material. In one example, the selective metal is tungsten (W). In one example, the selective metal may be ruthenium (Ru), molybdenum (Mo) or cobalt (Co). In one example, the selective metal includes an adhesion layer. In one example, the adhesion layer provides bonding between a metal and the dielectric material. In one example, the super via is fully filled with the selective metal. In one example, the super via is partially filled with the selective metal. In one example, the super via is formed using a single damascene process. In one example, the super via is formed using a dual damascene process. In one example, the selective metal is in contact with the dielectric material.

Another aspect of the disclosure provides a method for super via integration in an integrated circuit, the method including: forming a plurality of metal layers within a dielectric material; growing a selective metal nucleation layer on at least one of the plurality of metal layers; and integrating a super via between at least two of the plurality of metal layers using a selective metal on the selective metal nucleation layer, wherein the at least two of the plurality of metal layers are non-adjacent.

In one example, the super via does not include a barrier layer. In one example, the selective metal is tungsten (W). In one example, the selective metal may be ruthenium (Ru), molybdenum (Mo) or cobalt (Co). In one example, the method further includes fully filling the super via with the selective metal. In one example, the method further includes partially filling the super via with the selective metal. In one example, the method further includes using a single damascene process for integrating the super via between the at least two of the plurality of metal layers. In one example, the method further includes using a carbonyl precursor or a chlorine precursor and hydrogen for integrating the super via between the at least two of the plurality of metal layers. In one example, the method further includes using a dual damascene process for integrating the super via between the at least two of the plurality of metal layers.

Another aspect of the disclosure provides a computer-readable medium storing computer executable code, operable on a device comprising at least one processor and at least one memory coupled to the at least one processor, wherein the at least one processor is configured to implement a super via integration in an integrated circuit, the computer executable code including instructions for causing a computer to form a plurality of metal layers within a dielectric material; instructions for causing the computer to grow a selective metal nucleation layer on at least one of the plurality of metal layers; and instructions for causing the computer to integrate a super via between at least two of the plurality of metal layers using a selective metal on the selective metal nucleation layer, wherein the at least two of the plurality of metal layers are non-adjacent.

In one example, the computer-readable medium further includes instructions for causing the computer to partially fill the super via with the selective metal. In one example, the computer-readable medium further includes instructions for causing the computer to fully fill the super via with the selective metal. In one example, the computer-readable medium further includes instructions for causing the computer to use a single damascene process for integrating the super via between the at least two of the plurality of metal layers. In one example, the computer-readable medium further includes instructions for causing the computer to use a carbonyl precursor or a chlorine precursor and hydrogen for integrating the super via between the at least two of the plurality of metal layers. In one example, the computer-readable medium further includes instructions for causing the computer to use a dual damascene process for integrating the super via between the at least two of the plurality of metal layers. In one example, the computer-readable medium further includes instructions for causing the computer to use a carbonyl precursor or a chlorine precursor and hydrogen for integrating the super via between the at least two of the plurality of metal layers.

These and other aspects of the disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates an example of a via arrangement for an integrated circuit (IC).

FIG. 2 illustrates an example of a super via arrangement for an integrated circuit (IC).

FIG. 3 illustrates an example of a first super via integration process flow.

FIG. 4 illustrates an example of a second super via integration process flow.

FIG. 5 illustrates an example of a third super via integration process flow.

FIG. 6 illustrates an example of a fourth super via integration process flow.

FIG. 7 illustrates an example of a general process for super via integration.

FIG. 8 illustrates an example of a comparison between a selective tungsten process and a conventional tungsten process.

FIG. 9 illustrates an example of tungsten selective growth properties on different substrates.

FIG. 10 illustrates an example flow diagram 1000 for super via integration in an integrated circuit.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

Integrated circuits are fabricated with multiple layers, for example, stacked in a vertical direction. Layers may be interconnected using a via, that is, an electrical conductor within the integrated circuit. Typically, a via connects adjacent layers. In one example, two metal layers are adjacent if there are no other metal layers between them, even if the two metal layers are separated by a non-metal layer. Similarly, two metal layers are non-adjacent if they are separated by at least one other metal layer. Another form of via is known as a super via. For example, a super via is a via which connects non-adjacent layers. That is, a super via may connect layers which are not adjacent to each other. Some super via structures have complex integration (etching, metal filling, etc.) due to a high aspect ratio (height/width ratio) and due to different via heights.

Fabrication of ICs may involve two major processing steps: front end of line (FEOL) processing and back end of line (BEOL) processing. For example, FEOL processing may include device patterning within a semiconductor wafer (e.g., gate formation, source formation, drain formation for MOS transistors). FEOL processing may also include formation of a contacted poly pitch (CPP). For example, BEOL processing may include contact fabrication, wire interconnection, via formation and routing within the semiconductor wafer.

In one example, FEOL processing may be more difficult to scale than BEOL processing. Thus, some scaling may be implemented in BEOL processing. BEOL processing may include routing between layers. In one example, a super via may be used to route between non-adjacent layers with little impact to adjacent layers (e.g., in unidirectional designs). However, super via integration using certain techniques may be complicated to implement.

The present disclosure provides different integration processes to facilitate super via integration partially or fully filled with selective tungsten. For example, the super via may be fabricated at via level dielectrics to reduce an etch aspect ratio. For example, tungsten (atomic symbol W) may be partially or fully selective to reduce aspect ratio for copper (atomic symbol Cu) filling. For example, barrier thickness for a top copper layer may be reduced since the aspect ratio for copper filling is reduced. For example, a barrier between a bottom metal layer (e.g., copper, cobalt, tungsten) and a via with tungsten may not be needed since tungsten selectively grows on the bottom metal layer.

In one example, the integrated circuit (IC) includes a plurality of metal layers separated by a dielectric material. For example, a first metal layer may be denoted as M1, a second metal layer as M2, etc. A kth metal layer may be denoted as Mk. In one example, a super via is a via which interconnects a layer Mk with a layer M(k+n), where n≥2. That is, a super via is a via which interconnects non-adjacent layers.

In one example, the super via may have a low contact resistance due to a reduced via bottom barrier. For example, the super via may have a low impact on metal routing due to an omission of a metal island. In one example, integration of the super via (e.g., etch, metal fill, etc.) may be complex due to a high aspect ratio and different via heights.

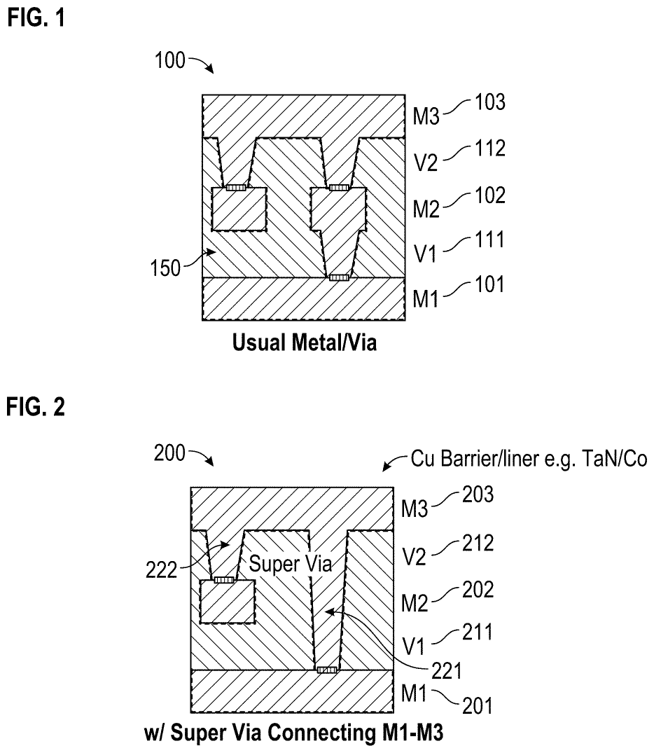

FIG. 1 illustrates an example of a via arrangement for an integrated circuit (IC) 100. Shown in FIG. 1 are a first metal layer M1 101, a second metal layer M2 102 and a third metal layer M3 103. Also shown are a first via layer V1 111 and a second via layer V2 112. In this example, vias interconnect adjacent metal layers. For example, a via in the first via layer V1 111 interconnects the first metal layer M1 101 and the second metal layer M2 102. For example, vias in the second via layer V2 112 interconnect the second metal layer M2 102 and the third metal layer M3 103. In one example, vias are surrounded by dielectric material 150.

FIG. 2 illustrates an example of a super via arrangement for an integrated circuit (IC) 200. Shown in FIG. 2 are a first metal layer M1 201, a second metal layer M2 202 and a third metal layer M3 203 with dielectric material between the metal layers. Also shown are a first via layer V1 211 and a second via layer V2 212. In this example, a super via 221 interconnects the first metal layer M1 201 and the third metal layer M3 203. That is, the super via 221 interconnects non-adjacent metal layers. In addition, a via 222 interconnects the second metal layer M2 202 and the third metal layer M3 203.

In one example, the super via 221 and via 222 may be made of copper (Cu). For example, copper may diffuse into the dielectric material. Since this diffusion is undesirable, the via may need to be augmented with a barrier layer for protection. In one example, the barrier layer may be needed on the bottom and the side portions of the via. In another example, the widths of either or both vias 221, 222 may be narrow and may result in difficulty of filling copper into a void (e.g., trench) of the super via 221 and via 222.

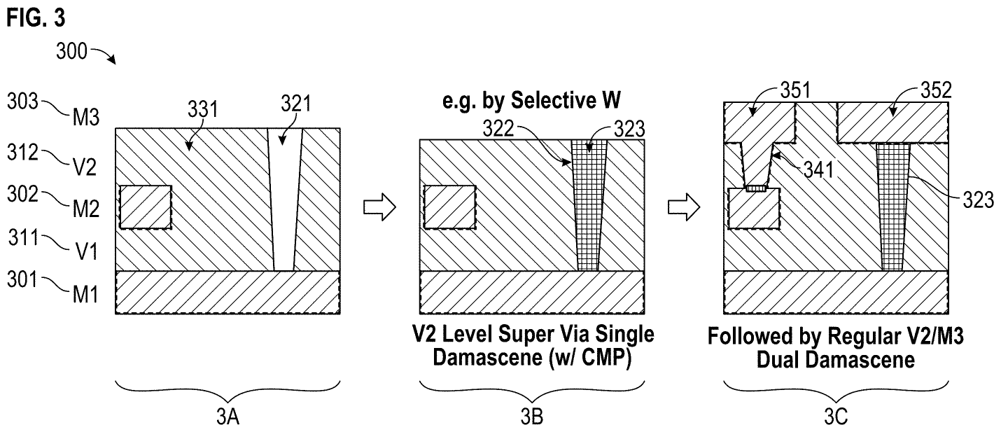

FIG. 3 illustrates an example of a first super via integration process flow 300. Shown in FIG. 3 are a first metal layer M1 301, a second metal layer M2 302 and a third metal layer M3 303 with a dielectric material 331 between the metal layers. In one example, the dielectric material 331 includes an etch stop layer (ESL) and a low k dielectric layer. For example, the ESL may include an aluminum nitrate (AlN) layer and a silicon carbon nitrate (SiCN) layer. Also shown are a first via layer V1 311 and a second via layer V2 312. The drawing on the left portion of FIG. 3 (labeled as 3A) shows a first step in a BEOL process for IC fabrication with a trench 321 through the second metal layer M2 302 and the dielectric material 331, where the trench 321 is between the first metal layer M1 301 and the third metal layer M3 303. The third metal layer M3 303 is shown on the right portion of FIG. 3 (labeled as 3C). The drawing on the middle portion of FIG. 3 (labeled as 3B) shows a second step in the BEOL process with the trench 321 filled with a selective metal 322 to form a super via 323.

In one example, the selective metal 322 grows on a metal surface at a higher rate than on a dielectric surface (e.g., FIG. 9) by using a specific precursor and/or a specific deposition method or conditions. That is, the selective metal 322 growth is selective on the metal surface over the dielectric surface. For example, the selective metal 322 growth may be bottom-up growth (i.e., growth from the bottom) since the bottom of trench 321 is metal and its sidewall is dielectric. For example, bottom-up growth is suitable for a high aspect ratio via (i.e., aspect ratio is a ratio of height to lateral size or width) with low overburden since a top surface is dielectric with slow growth. For example, overburden refers to top surface growth after high aspect ratio via growth. For example, since selectivity is finite, there is eventually some growth on the dielectric. In another example, the selective metal 322 requires no barrier layer. For example, a conventional metal growth process first grows a thin layer (e.g. titanium nitride, TiN) with a high resistivity. For example, selective metal growth does not require a thin layer with high resistivity and hence may have a low via resistance.

In one example, the selective metal may be tungsten (W). In another example, the selective metal may be selective ruthenium (Ru) or selective cobalt (Co). For example, the first metal layer M1 301 may be made of tungsten (W), cobalt (Co), or ruthenium (Ru), molybdenum (Mo), etc. In one example, the super via 323 may be formed using a single damascene process (e.g., layer by layer process) using chemical mechanical polishing (CMP).

The drawing on the right portion of FIG. 3 (labeled as 3C) shows a third step in the BEOL process with a via 341 in the second via layer 312 interconnecting the second metal layer M2 302 and the third metal layer M3 303. In addition, there is a first metal element 351 in the third metal layer M3 303 connected to via 341 and a second metal element 352 in the third metal layer M3 303 connected to super via 323. In one example, tungsten may have no barrier layer. In one example, cobalt and ruthenium may have an adhesion layer. The adhesion layer may increase bonding between a metal and dielectric. The adhesion layer may have a thickness of less than 1 nm. In one example, copper may have a barrier layer. The barrier layer may prevent diffusion into a dielectric. In one example, the barrier layer may have a thickness of 2 nm or more.

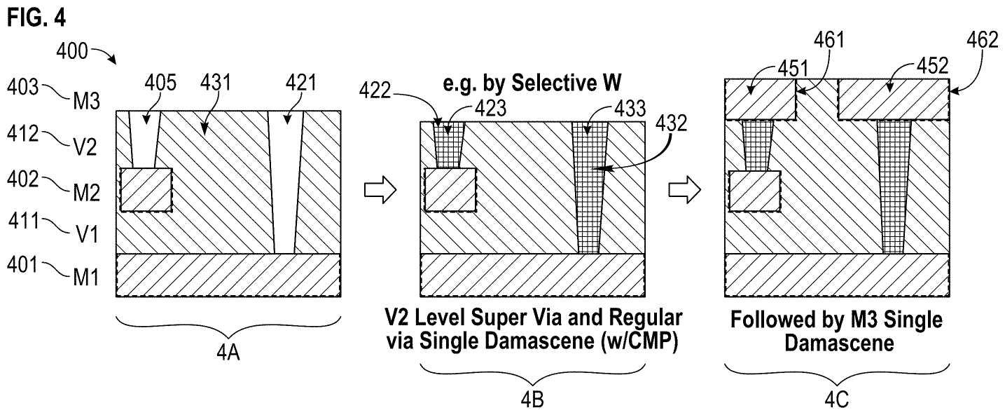

FIG. 4 illustrates an example of a second super via integration process flow 400. Shown in FIG. 4 are a first metal layer M1 401, a second metal layer M2 402 and a third metal layer M3 403. Also shown are a first via layer V1 411 and a second via layer V2 412. The drawing on the left portion of FIG. 4 (labeled as 4A) shows a first step in a BEOL process for IC fabrication with a first trench 405 between the second metal layer M2 402 and the third metal layer M3 403. The third metal layer M3 403 is shown on the right portion of FIG. 4 (labeled as 4C). The first trench 405 is through a dielectric material 431. The left portion of FIG. 4 (labeled as 4A) also shows a second trench 421 through the second metal layer M2 402 and the dielectric material 431, where the second trench 421 is between the first metal layer M1 401 and the third metal layer M3 403. The third metal layer M3 403 is shown on the right portion of FIG. 4 (labeled as 4C).

The drawing on the middle portion of FIG. 4 (labeled as 4B) shows a second step in the BEOL process with the trench 405 filled with a first selective metal 422 to form a via 423 and the second trench 421 filled with a second selective metal 432 to form a super via 433. In one example, the selective metal (e.g., first selective metal 422, second selective metal 432 or both) may be tungsten (W). In another example, the selective metal (e.g., first selective metal 422, second selective metal 432 or both) may be selective ruthenium (Ru) or selective cobalt (Co). In one example, the via 423 and the super via 433 may be formed using a single damascene process (e.g., a single copper interconnect) using chemical mechanical polishing (CMP).

The drawing on the right portion of FIG. 4 (labeled as 4C) shows a third step in the BEOL process with addition of a first metal element 451 in the third metal layer M3 403 connected to via 423 and a second metal element 452 in the third metal layer M3 403 connected to super via 433. In one example, the third step uses a single damascene process. For example, the first metal element 451 and the second metal element 452 may have a reduced aspect ratio. In one example, a first barrier layer 461 and a second barrier layer 462 may have a lower thickness and lower contact resistance.

For example, a dual damascene process may deposit a tantalum nitride (TaN) barrier with 2-3 nm thickness. For example, a selective metal process using tungsten (W) may not require a barrier layer and hence via resistance may be lowered (since the barrier layer bottom may be a main contributor to via resistance). For example, a selective metal process using ruthenium (Ru) may use a thin adhesion layer (e.g. TiN) with approximately 0.3 nm thickness. For example, a selective metal process using cobalt (Co) may use a thin barrier layer with approximately 1 nm thickness. In one example, a selective metal process with a barrier layer may have a via resistance lower by approximately 20-40% compared to a process with a 2-4 nm thick barrier layer.

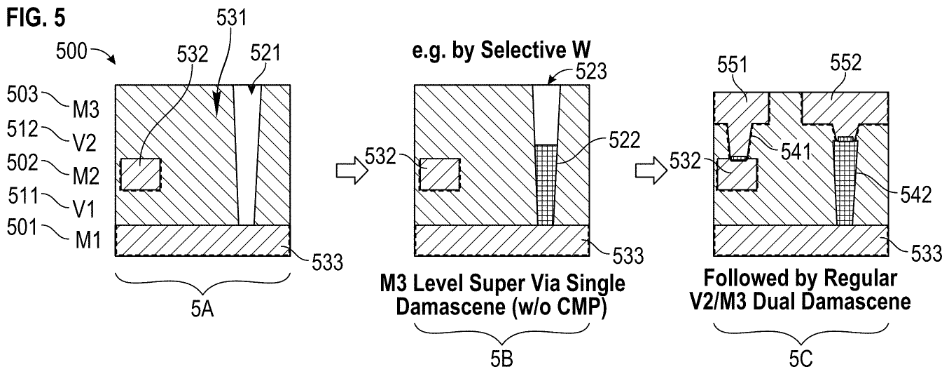

FIG. 5 illustrates an example of a third super via integration process flow 500. Shown in FIG. 5 are a first metal layer M1 501, a second metal layer M2 502 and a third metal layer M3 503. Also shown are a first via layer V1 511 and a second via layer V2 512. The drawing on the left portion of FIG. 5 (labeled as 5A) shows a first step in a BEOL process for IC fabrication with a trench 521 through the second metal layer M2 502 and a dielectric material 531, where the trench 521 is between the first metal layer M1 501 and the third metal layer M3 503. In addition, there is a first metal element 533 in the first metal layer M1 501 and a second metal element 532 in the second metal layer M2 502.

The drawing on the middle portion of FIG. 5 (labeled as 5B) shows a second step in a BEOL process for IC fabrication with a partially filled trench 523 containing a selective metal 522. In one example, the selective metal may be tungsten (W). In another example, the selective metal may be selective ruthenium (Ru) or selective cobalt (Co). In one example, the partially filled trench 523 may be formed using a single damascene process without using chemical mechanical polishing (CMP).

The drawing on the right portion of FIG. 5 (labeled as 5C) shows a third step in a BEOL process for IC fabrication with a first metal element 551 in the third metal layer M3 503 connected to a via 541 and a second metal element 552 in the third metal layer M3 503 connected to a super via 542. For example, the via 541 is connected to the second metal element 532. For example, the super via 542 is connected to the first metal element 533. In one example, the third step may be performed using a dual damascene process (e.g., a dual layer process).

In one example, for a typical dual damascene process, metal layer height may be two times of minimal metal layer width, leading to an aspect ratio of 2. A typical (e.g., final) via also may have an aspect ratio of 2. For example, the selective W via 323 aspect ratio is approximately 6, via 423 has an aspect ratio of approximately 2, super via 542 has an aspect ratio of approximately 5, but the via of the partially filled trench 523 (during etch process) has an aspect ratio of approximately 8 and the height of partially filled trench 523 equals the sum of the V1 height, M2 height, V2 height, and M3 height. For example, the via in the present disclosure (e.g. latest process of most advanced technology nodes) may have a via aspect ratio of 1 to 1.5 compared to approximately 2 for typical via aspect ratio.

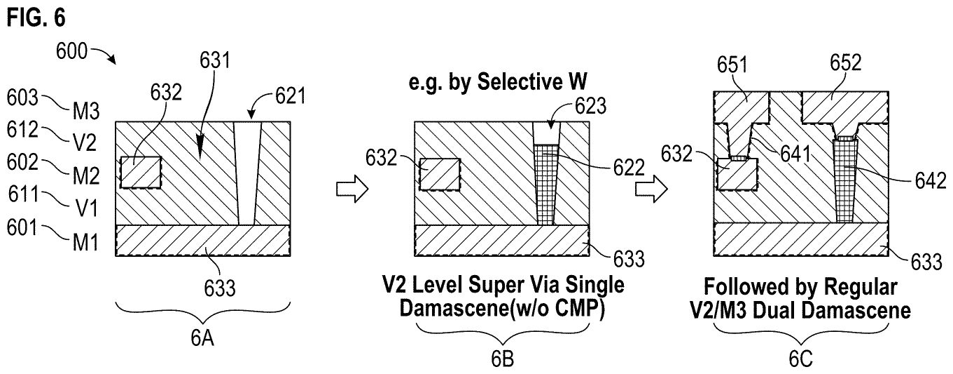

FIG. 6 illustrates an example of a fourth super via integration process flow 600. Shown in FIG. 6 are a first metal layer M1 601, a second metal layer M2 602 and a third metal layer M3 603. Also shown are a first via layer V1 611 and a second via layer V2 612. The drawing on the left portion of FIG. 6 (labeled as 6A) shows a first step in a BEOL process for IC fabrication with a trench 621 through the second metal layer M2 602 and a dielectric material 631, where the trench 621 is between the first metal layer M1 601 and the third metal layer M3 603. The third metal layer M3 603 is shown on the right portion of FIG. 6 (labeled as 6C). In one example, the trench 621 has a low aspect ratio. In addition, there is a first metal element 633 in the first metal layer M1 601 and a second metal element 632 in the second metal layer M2 602.

The drawing on the middle portion of FIG. 6 (labeled as 6B) shows a second step in a BEOL process for IC fabrication with a partially filled trench 623 containing a selective metal 622. In one example, the selective metal may be tungsten (W). In another example, the selective metal may be selective ruthenium (Ru) or selective cobalt (Co). In one example, the partially filled trench 623 may be formed using a single damascene process (e.g., a single copper interconnect) without using chemical mechanical polishing (CMP). In one example, the partially filled trench 623 has a low aspect ratio.

The drawing on the right portion of FIG. 6 (labeled as 6C) shows a third step in a BEOL process for IC fabrication with a first metal element 651 in the third metal layer M3 603 connected to a via 641 and a second metal element 652 in the third metal layer M3 603 connected to a super via 642. For example, the via 641 is connected to the second metal element 632. For example, the super via 642 is connected to the first metal element 633. In one example, the super via 642 has a low aspect ratio. In one example, the third step may be performed using a dual damascene process.

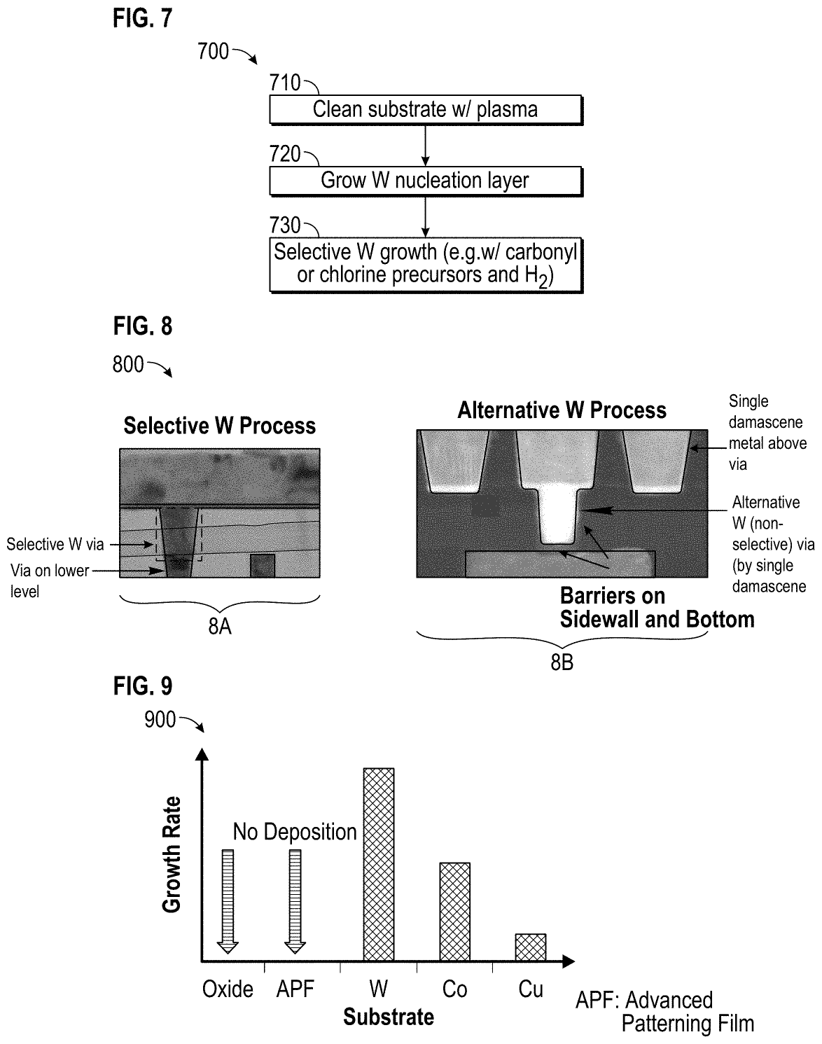

FIG. 7 illustrates an example of a general process 700 for super via integration. In block 710, clean a substrate with a plasma. In block 720, grow a selective metal nucleation layer. In one example, the selective metal is tungsten. In block 730, grow a selective metal on the selective metal nucleation layer. In one example, the growth uses carbonyl or chorine precursors and hydrogen. In one example, hydrogen gas may be used. In another example, hydrogen liquid may be used. In one aspect, super via integration in an integrated circuit is achieved by forming a plurality of metal layers within a dielectric material, by growing a selective metal nucleation layer on at least one of the plurality of metal layers, and by integrating a super via between at least two of the plurality of metal layers using a selective metal on the selective metal nucleation layer. In one example, the at least two of the plurality of metal layers are non-adjacent.

FIG. 8 illustrates an example of a comparison 800 between a selective tungsten process (labeled as 8A) and an alternative tungsten process (labeled as 8B). In one example, transmission electron microscopy (TEM) imagery shows barrier layers (e.g. in sidewall and bottom) in the alternative tungsten process and no barrier layers in the selective tungsten process. In one example, the selective tungsten process (labeled as 8A) includes a selective W via (shown with upper dashed lines) and a lower level via (shown with lower dashed lines). For example, the alternative tungsten process (labeled as 8B) includes an alternative W via (shown in the middle) formed with a single damascene process. In addition a single damascene metal may be positioned above the via.

FIG. 9 illustrates an example 900 of tungsten selective growth properties on different substrates. In one example, tungsten may grow selectively at a higher growth rate on substrates with tungsten, cobalt, or copper and may have no growth on dielectrics, such as oxide or advanced patterning film (APF).

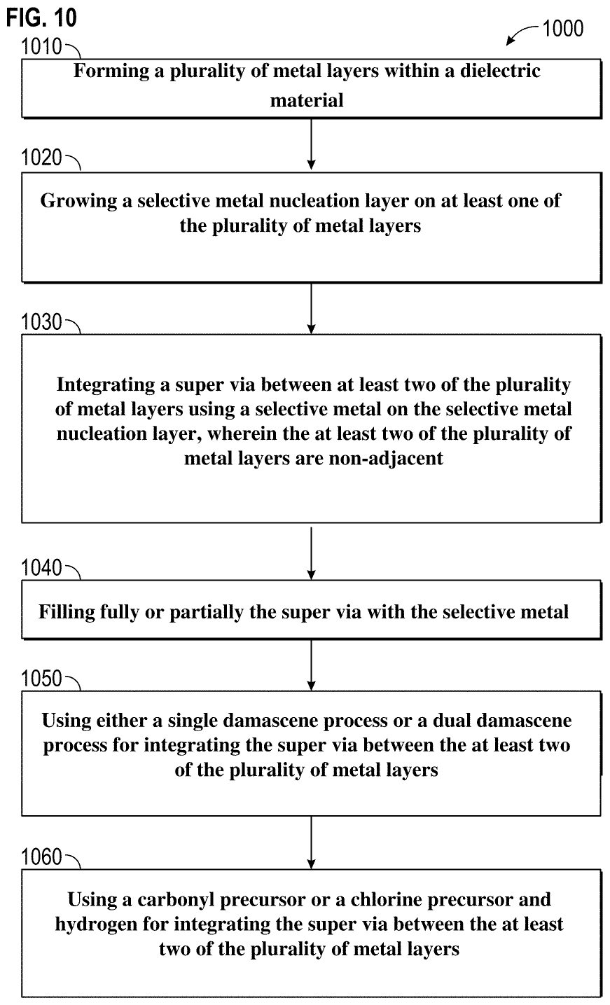

FIG. 10 illustrates an example flow diagram 1000 for super via integration in an integrated circuit. In box 1010, form a plurality of metal layers within a dielectric material. In box 1020, grow a selective metal nucleation layer on at least one of the plurality of metal layers. In box 1030, integrate a super via between at least two of the plurality of metal layers using a selective metal on the selective metal nucleation layer, wherein the at least two of the plurality of metal layers are non-adjacent. In box 1040, fill fully or partially the super via with the selective metal. In box 1050, use either a single damascene process or a dual damascene process for integrating the super via between the at least two of the plurality of metal layers. In box 1060, use a carbonyl precursor or a chlorine precursor and hydrogen for integrating the super via between the at least two of the plurality of metal layers.

In one aspect, any and all of the various embodiments disclosed herein may be manufactured by the processes illustrated in FIG. 7 and/or FIG. 10. In one aspect, one or more of the steps for providing for super via integration in FIG. 7 and/or FIG. 10 may be executed by one or more processors which may include hardware, software, firmware, etc. In one aspect, one or more of the steps in FIG. 7 and/or FIG. 10 may be executed by one or more processors which may include hardware, software, firmware, etc. The one or more processors, for example, may be used to execute software or firmware needed to perform the steps in the flow diagrams of FIG. 7 and/or FIG. 10. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in a processing system, external to the processing system, or distributed across multiple entities including the processing system. The computer-readable medium may be embodied in a computer program product. By way of example, a computer program product may include a computer-readable medium in packaging materials. The computer-readable medium may include software or firmware for super via integration. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

1. An apparatus with super via integration in an integrated circuit, the apparatus comprising:
a first metal layer;
a second metal layer, wherein the second metal layer is adjacent to the first metal layer;
a third metal layer, wherein the third metal layer is adjacent to the second metal layer and is non-adjacent to the first metal layer; and
a super via interconnecting the first metal layer and the third metal layer through a dielectric material, wherein the super via is filled with a selective metal.

2. The apparatus of claim 1, wherein the super via is filled into a trench in the dielectric material.

3. The apparatus of claim 1, wherein the selective metal is tungsten (W).

4. The apparatus of claim 1, wherein the selective metal is either ruthenium (Ru) or cobalt (Co).

5. The apparatus of claim 4, wherein the selective metal includes an adhesion layer.

6. The apparatus of claim 5, wherein the adhesion layer provides bonding between a metal and the dielectric material.

7. The apparatus of claim 1, wherein the super via is fully filled with the selective metal.

8. The apparatus of claim 1, wherein the super via is partially filled with the selective metal.

9. The apparatus of claim 1, wherein the super via is formed using a single damascene process.

10. The apparatus of claim 1, wherein the super via is formed using a dual damascene process.

11. The apparatus of claim 1, wherein the selective metal is in contact with the dielectric material.

12. A method for super via integration in an integrated circuit, the method comprising:
forming a plurality of metal layers within a dielectric material;
growing a selective metal nucleation layer on at least one of the plurality of metal layers; and
integrating a super via between at least two of the plurality of metal layers using a selective metal on the selective metal nucleation layer, wherein the at least two of the plurality of metal layers are non-adjacent.

13. The method of claim 12, wherein the super via does not include a barrier layer.

14. The method of claim 12, wherein the selective metal is tungsten (W).

15. The method of claim 12, wherein the selective metal is either ruthenium (Ru) or cobalt (Co).

16. The method of claim 12, further comprising fully filling the super via with the selective metal.

17. The method of claim 12, further comprising partially filling the super via with the selective metal.

18. The method of claim 12, further comprising using a single damascene process for integrating the super via between the at least two of the plurality of metal layers.

19. The method of claim 18, further comprising using a carbonyl precursor or a chlorine precursor and hydrogen for integrating the super via between the at least two of the plurality of metal layers.

20. The method of claim 12, further comprising using a dual damascene process for integrating the super via between the at least two of the plurality of metal layers.

21. The method of claim 20, further comprising using a carbonyl precursor or a chlorine precursor and hydrogen for integrating the super via between the at least two of the plurality of metal layers.

22. A computer-readable medium storing computer executable code, operable on a device comprising at least one processor and at least one memory coupled to the at least one processor, wherein the at least one processor is configured to implement a super via integration in an integrated circuit, the computer executable code comprising:
instructions for causing a computer to form a plurality of metal layers within a dielectric material;
instructions for causing the computer to grow a selective metal nucleation layer on at least one of the plurality of metal layers; and
instructions for causing the computer to integrate a super via between at least two of the plurality of metal layers using a selective metal on the selective metal nucleation layer, wherein the at least two of the plurality of metal layers are non-adjacent.

23. The computer-readable medium of claim 22, further comprising instructions for causing the computer to partially fill the super via with the selective metal.

24. The computer-readable medium of claim 22, further comprising instructions for causing the computer to fully fill the super via with the selective metal.

25. The computer-readable medium of claim 22, further comprising instructions for causing the computer to use a single damascene process for integrating the super via between the at least two of the plurality of metal layers.

26. The computer-readable medium of claim 25, further comprising instructions for causing the computer to use a carbonyl precursor or a chlorine precursor and hydrogen for integrating the super via between the at least two of the plurality of metal layers.

27. The computer-readable medium of claim 22, further comprising instructions for causing the computer to use a dual damascene process for integrating the super via between the at least two of the plurality of metal layers.

28. The computer-readable medium of claim 27, further comprising instructions for causing the computer to use a carbonyl precursor or a chlorine precursor and hydrogen for integrating the super via between the at least two of the plurality of metal layers.
